(19) United States
(12) Patent Application Publication
(10) Pub. No.: US 2025/0091062 A1
(43) Pub. Date: Mar. 20, 2025

(54) NOZZLE MODULE AND SUBSTRATE PROCESSING APPARATUS INCLUDING THE SAME

(71) Applicant: SEMES CO., LTD., Cheonan-si (KR)

(72) Inventors: Jae Hyun LIM, Asan-si (KR); Dae Sung KIM, Suwon-si (KR); Jong Gu LEE, Sangju-si (KR); Jae Ho LEE, Cheonan-si (KR); Nak Hyun SONG, Cheonan-si (KR)

(21) Appl. No.: 18/783,344

(22) Filed: Jul. 24, 2024

(30) Foreign Application Priority Data
Sep. 14, 2023 (KR) 10-2023-0122449

(51) Int. Cl. B05B 3/18; B05B 1/28; B05C 13/00

(52) U.S. Cl. CPC B05B 3/18; B05C 13/00; B05B 1/28

(57) ABSTRACT

A nozzle module includes a base portion; a nozzle portion disposed on the base portion, and including a first body, and a nozzle portion reciprocating in a first movement direction; and a vessel unit disposed to face the nozzle portion, and including a second body reciprocating in a second movement direction, and an accommodation portion concavely formed inwardly from an upper surface of the second body.

### CROSS-REFERENCE TO RELATED APPLICATION(S)

This application claims benefit of priority to Korean Patent Application No. 10-2023-0122449 filed on Sep. 14, 2023 in the Korean Intellectual Property Office, the disclosure of which is incorporated herein by reference in its entirety.

### BACKGROUND

### 1. Field

The present disclosure relates to a nozzle module and a substrate processing apparatus including the same.

### 2. Description of Related Art

To manufacture semiconductor devices, various processes such as a cleaning process, a deposition process, a photolithography process, an etching process, an ion implantation process, and the like may be performed. Among these processes, the photolithography process may include a coating process in which a photosensitive liquid such as photoresist is applied to a surface of a substrate to form a film, an exposure process in which a circuit pattern is transferred to the film formed on the substrate, and a development process of selectively removing the film formed on the substrate in an exposed region or a region opposite thereto.

In a liquid treatment process, a processing liquid may be supplied in a position in which a nozzle faces the substrate while the process is in progress, and the nozzle may wait in a standby port, before and after the process. The standby port may include a common body including an accommodating space, and a plurality of nozzles may be accommodated in the accommodating space of the common body. While the plurality of nozzles accommodated in the receiving space wait, a cleaning liquid may be discharged toward a discharge end of the nozzle, and the discharge end and a surrounding portion thereof may be cleaned together.

Generally, a liquid treatment process may be carried out using a plurality of nozzles, and these nozzles may be installed on a nozzle arm, and may integratedly move as the nozzle arm moves in left and right directions and in upward and downward directions. PR may be periodically discharged and cleaned through the nozzles, and even during nozzle cleaning, the plurality of nozzles may move and cleaned to a home pot together. In this case, there may be a problem that production loss occurs and chemical consumption also increases because all nozzles, including nozzles unnecessary for cleaning, move to the home pot and cleaning is performed.

### SUMMARY

An aspect of the present disclosure is to provide a nozzle module and a substrate processing apparatus, which may reduce an amount of a chemical liquid consumed in a semiconductor substrate processing process, and may reduce semiconductor device production loss.

According to an aspect of the present disclosure, a nozzle module includes a base portion; a nozzle unit disposed on the base portion, and including a first body, and a nozzle portion reciprocating in a first movement direction; and a vessel unit disposed to face the nozzle unit, and including a second body reciprocating in a second movement direction, and an accommodation portion concavely formed inwardly from an upper surface of the second body.

According to another aspect of the present disclosure, a substrate processing apparatus includes a processing chamber; at least two processing units disposed in the processing chamber, including a processing vessel accommodating a substrate, and a support portion disposed in the processing vessel and supporting the substrate; and a nozzle module disposed in the processing chamber, and including a base portion, a nozzle unit disposed on the base portion, and including a first body, and a nozzle portion reciprocating in a first movement direction, a vessel unit disposed to face the nozzle portion, and including a second body reciprocating in a second movement direction, and an accommodation portion concavely formed inwardly from an upper surface of the second body, and a support unit including a support member disposed on the base portion, a guide portion disposed on the support member, a connection portion connected to the guide portion to reciprocate in a third movement direction, and a support plate connecting the connection portion and the nozzle unit.

According to another aspect of the present disclosure, a substrate processing apparatus includes a processing chamber; at least two processing units disposed in the processing chamber, including a processing vessel accommodating a substrate, and a support portion disposed in the processing vessel and supporting the substrate; and a nozzle module disposed in the processing chamber, and including a base portion, a nozzle unit disposed on the base portion, and including a first body, a nozzle portion reciprocating in a first movement direction, a first driver disposed on an upper surface of the first body to generate driving force necessary for moving the nozzle portion, and a conversion member disposed between the first driver and the nozzle portion to convert a direction of the driving force to the first movement direction, a vessel unit disposed to face the nozzle unit, including a second body reciprocating in a second movement direction, and an accommodation portion concavely formed inwardly from an upper surface of the second body, and disposed to face the nozzle portion, and a support unit including a support member disposed on the base portion, a guide portion disposed on the support member, a connection portion connected to the guide portion to reciprocate in a third movement direction, and a support plate connecting the connection portion and the nozzle unit, wherein the nozzle portion is disposed above the second body, and extends toward the accommodation portion in a downward direction, and is raised and lowered between the first driving portion and the accommodation portion, one end of the first body has an inclined surface portion, the inclined surface portion is disposed below the conversion member, and is formed by connecting a plurality of inclined surfaces having different inclination angles, the nozzle portion is provided in plural, the plurality of nozzle portions are arranged to be spaced apart in a longitudinal direction of the first body, and at least a portion of the plurality of nozzle portions are independently raised and lowered, and the vessel unit is provided in plural, the plurality of vessel units are arranged to face the plurality of nozzle portions one to one, and at least a portion of the second body independently reciprocates.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view of a substrate processing apparatus, viewed from above.

FIG. 2 is a view of the substrate processing apparatus of FIG. 1, viewed in an A-A direction.

FIG. 3 is a view of the substrate processing apparatus of FIG. 1, viewed in a B-B direction.

FIG. 4 is a perspective view illustrating a nozzle module and a peripheral portion thereof according to an embodiment of the present disclosure.

FIG. 5 is an enlarged perspective view of a portion of the nozzle module of FIG. 4.

FIG. 6 is a side view illustrating the nozzle module of FIG. 4, viewed from one side.

FIG. 7 is a side view illustrating one state of the nozzle module of FIG. 4.

FIG. 8 is a side view illustrating another state of the nozzle module of FIG. 4.

FIG. 9 is a side view illustrating the other state of the nozzle module of FIG. 4.

### DETAILED DESCRIPTION

Hereinafter, with reference to the attached drawings, preferred embodiments will be described in detail such that those skilled in the art may easily practice the present disclosure. However, when describing preferred embodiments of the present disclosure in detail, and it is determined that a detailed description of a related known function or configuration may unnecessarily obscure the gist of the present disclosure, the detailed description will be omitted. In addition, the same symbols may be used throughout the drawings for parts that perform similar functions and actions. In addition, in this specification, terms such as ‘on,’ ‘upper portion,’ ‘upper end,’ ‘below,’ ‘lower portion,’ ‘lower end,’ and the like may be based on the drawings, and terms such as ‘in,’ ‘within,’ ‘inside,’ ‘outside,’ and the like may also be based on an outer edge of a component corresponding thereto, and may actually vary depending on a direction in which an element or a component is disposed.

In addition, throughout the specification, ‘including’ a certain component means that other elements may be further included, rather than excluding another component, unless specifically stated to the contrary.

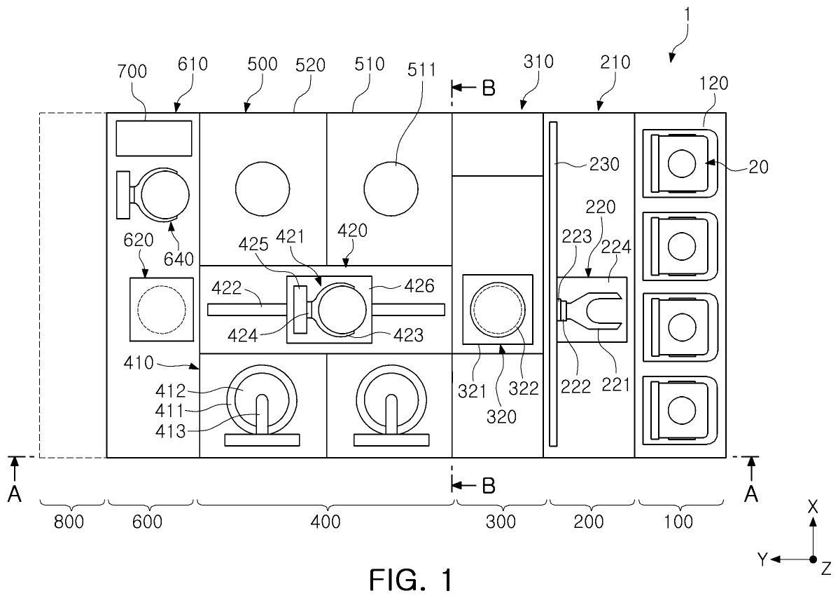

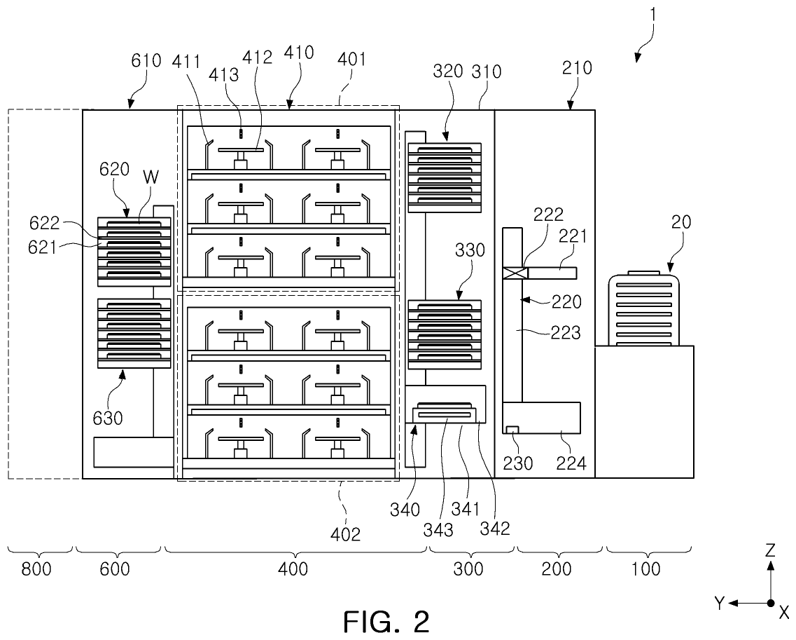

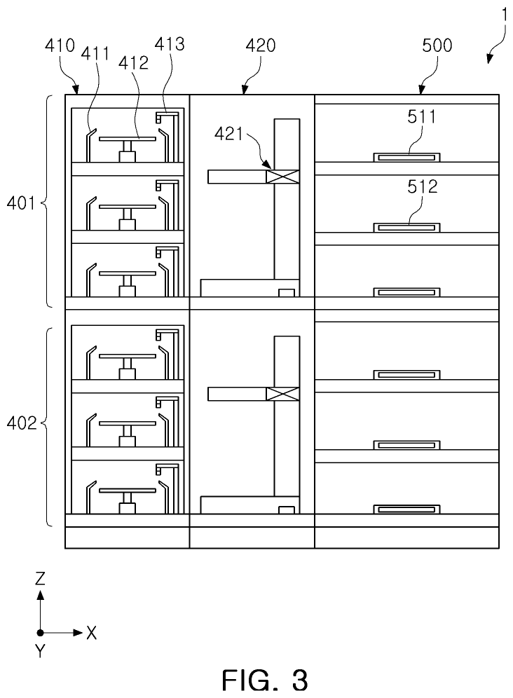

FIG. 1 is a view of a substrate processing apparatus, viewed from above. FIG. 2 is a view of the substrate processing apparatus of FIG. 1, viewed in an A-A direction. FIG. 3 is a view of the substrate processing apparatus of FIG. 1, viewed in a B-B direction.

Referring to FIGS. 1 to 3, a substrate processing apparatus 1 may include a load port 100, an index module 200, a buffer module 300, an applying/development module 400, an interface module 600, and a purge module 700. The load port 100, the index module 200, the buffer module 300, the applying/development module 400, and the interface module 600 may be sequentially arranged in one direction. The purge module 700 may be provided in the interface module 600. The purge module 700 may be provided in various positions, such as in a position in which an exposure device 800 is connected to a rear end of the interface module 600, a side portion of the interface module 600, or the like. Hereinafter, a direction in which the load port 100, the index module 200, the buffer module 300, the applying/development module 400, and the interface module 600 are arranged may be referred to as a first direction Y, a direction, perpendicular to the first direction Y, when viewed from above, may be referred to as a second direction X, and a direction, perpendicular to the first direction Y and the second direction X, may be referred to as a third direction Z.

A substrate W may move in a state of being accommodated in a cassette 20. The cassette 20 may have a structure that may be sealed from the outside. For example, a front opening unified pod (FOUP) having a door in a front direction may be used as the cassette 20.

Hereinafter, the load port 100, the index module 200, the buffer module 300, the applying/development module 400, the interface module 600, and the purge module 700 will be described in detail.

The load port 100 may have a placing table 120 on which the cassette 20 in which the substrate W is accommodated is disposed. The placing table 120 may be provided in plural, and the plurality of placing tables 120 may be arranged in a row in the second direction X. FIG. 1 illustrates an example in which four placing tables 120 are provided, but the number thereof may be changed.

The index module 200 may transfer the substrate W between the cassette 20 disposed on the placing table 120 of the load port 100, and the buffer module 300. The index module 200 may include a frame 210, an index robot 220, and a guide rail 230.

The frame 210 may be generally provided in a rectangular hexahedral shape having an empty interior, and may be disposed between the load port 100 and the buffer module 300. The frame 210 of the index module 200 may be provided on a lower height than a frame 310 of the buffer module 300.

The index robot 220 and the guide rail 230 may be arranged in the frame 210. The index robot 220 may be provided such that a gripper 221, which directly handles the substrate W, may move and rotate in the first direction Y, the second direction X, and the third direction Z. The index robot 220 may include the gripper 221, an arm 222, a support 223, and a pedestal 224. The gripper 221 may be fixedly installed on the arm 222. The arm 222 may be provided to as a stretchable structure or a rotatable structure. A longitudinal direction of the support 223 may be disposed in the third direction Z. The arm 222 may be coupled to the support 223 to be movable along the support 223. The support 223 may be fixedly coupled to the pedestal 224. The guide rail 230 may be provided such that a longitudinal direction thereof is disposed in the second direction X. The pedestal 224 may be coupled to the guide rail 230 to move linearly along the guide rail 230. In addition, although not illustrated, the frame 210 may be further provided with a door opener for opening and closing the door of the cassette 20.

The buffer module 300 may include the frame 310, a first buffer 320, a second buffer 330, and a cooling chamber 340. The frame 310 may be provided in a rectangular hexahedral shape having an empty interior, and may be disposed between the index module 200 and the applying/development module 400. The first buffer 320, the second buffer 330, and the cooling chamber 340 may be located in the frame 310. The cooling chamber 340, the second buffer 330, and the first buffer 320 may be sequentially arranged in the third direction Z from below. The first buffer 320 may be located on a height corresponding to an application module 401 of the applying/development module 400, and the second buffer 330 and the cooling chamber 340 may be located on a height corresponding to a development module 402 of the applying/development module 400.

The first buffer 320 and the second buffer 330 may temporarily store a plurality of substrates W, respectively. The first buffer 320 may have a housing 321 and a plurality of supports 322. In the first buffer 320, the supports 322 may be disposed in the housing 321, and may be spaced apart from each other in the third direction Z. The second buffer 330 may have a housing 331 and a plurality of supports 332. In the second buffer 330, the supports 332 may be disposed in the housing 331, and may be spaced apart from each other in the third direction Z. One substrate W may be disposed on each of the supports 322 of the first buffer 320 and each of the supports 332 of the second buffer 330. The housing 331 may have an opening in a direction in which the index robot 220 is provided such that the index robot 220 may load or unload the substrate W into or out of the support 332 in the housing 331.

The first buffer 320 may have a generally similar structure to the second buffer 330. The housing 321 of the first buffer 320 may have an opening in a direction in which a first buffer robot 360 is provided, and in a direction in which an application robot 421 located in an application module 401 is provided. The number of supports 322 provided in the first buffer 320 may be the same as or different from the number of supports 332 provided in the second buffer 330. According to an example, the number of supports 332 provided in the second buffer 330 may be greater than the number of supports 322 provided in the first buffer 320.

The cooling chambers 340 may cool the substrate W, respectively. The cooling chamber 340 may include a housing 341 and a cooling plate 342. The cooling plate 342 may have an upper surface on which the substrate W is disposed, and a cooling means 343 for cooling the substrate W. As the cooling means 343, various methods may be used, such as cooling using a coolant, cooling using a thermoelectric element, or the like. Additionally, the cooling chamber 340 may be provided with a lift pin assembly for locating the substrate W on the cooling plate 342. The housing 341 may have an opening in a direction in which the index robot 220 is provided and in a direction in which a developing robot provided in the developing module 402 is provided, such that the index robot 220 and the developing robot provided in the developing module 402 load or unload the substrate W to the cooling plate 342. Additionally, the cooling chamber 340 may be provided with doors opening and closing the above-described openings.

In the above, the buffer module 300 has been described as an embodiment including a configuration of the cooling chamber 340, but the present disclosure is not limited thereto, and the configuration of the cooling chamber 340 may be omitted, as necessary.

The application module 401 may include a process of applying a photosensitive liquid such as a photoresist to the substrate W, and a heat treatment process such as heating and cooling of the substrate W before and after a resist application process. The application module 401 may have an application chamber 410, a heat treatment chamber unit 500, and a transfer chamber 420. The application chamber 410, the transfer chamber 420, and the heat treatment chamber unit 500 may be sequentially arranged in the second direction X. For example, based on the transfer chamber 420, the application chamber 410 may be provided on one side of the transfer chamber 420, and the heat treatment chamber unit 500 may be provided on the other side of the transfer chamber 420.

The heat treatment chamber unit 500 may include a baking chamber 510 and a cooling chamber 520, and the baking chamber 510 and the cooling chamber 520 may be provided in plural, respectively, in the third direction Z. The transfer chamber 420 may be located parallel to the first buffer 320 of the buffer module 300 in the first direction Y. The application robot 421 and a guide rail 422 may be located in the transfer chamber 420. The transfer chamber 420 may have a generally rectangular shape. The application robot 421 may transfer the substrate W between the baking chamber 510, the cooling chamber 520, the application chamber 410, and the first buffer 320 of the buffer module 300.

The guide rail 422 may be disposed such that a longitudinal direction thereof is parallel to the first direction Y. The guide rail 422 may guide the application robot 421 to move linearly in the first direction Y. The application robot 421 may have a gripper 423, an arm 424, a support 425, and a pedestal 426. The gripper 423 may be fixedly installed on the arm 424. The arm 424 may be provided as a stretchable structure such that the gripper 423 may move in a horizontal direction. The support 425 may be provided such that a longitudinal direction thereof is disposed in the third direction Z. The arm 424 may be coupled to the support 425 to move linearly in the third direction Z along the support 425. The support 425 may be fixedly coupled to the pedestal 426, and the pedestal 426 may be coupled to the guide rail 422 to be movable along the guide rail 422.

The application chamber 410 may be provided in plural, and may be provided in plural in the third direction Z. Additionally, as illustrated in FIG. 1, the application chamber 410 may be provided in plural in the first direction Y, or one application chamber 410 may be provided in the first direction Y. When the application chamber 410 is provided in plural, the application chambers 410 may have the same structure. Types of processing liquids used in each of the application chambers 410 may be the same or different. As the processing liquid, for example, a processing liquid for forming a photoresist film or an anti-reflection film may be used.

The processing liquid may be applied on the substrate W in the application chamber 410. The application chamber 410 may have a processing unit including a processing vessel 411 and a support portion 412 therein. Additionally, a nozzle module 900 including a nozzle portion 922 may be disposed in the application chamber 410.

The processing vessel 411 may have a shape opened in an upward direction. The support portion 412 may be located in the processing vessel 411, and may support the substrate W. The support portion 412 may be provided to be rotatable. As an example, one processing unit may be disposed in the application chamber 410. However, the present disclosure is not limited thereto, and two or more processing units may be disposed in the application chamber 410. In this case, each of the processing units may have the same structure. Types of processing liquids used in each of the processing units may be different from each other.

The nozzle portion 922 of the nozzle module 900 may supply a processing liquid to the substrate W disposed on the support portion 412. The processing liquid may be applied to the substrate W using a spin coat method. The nozzle portion 922 and the nozzle module 900 including the same will be described in detail below.

A nozzle (not illustrated) for supplying a cleaning liquid such as deionized water (DIW) to clean a surface of the substrate W on which the processing liquid is applied, and a back rinse nozzle (not illustrated) for cleaning a lower surface of the substrate W may be optionally further provided in the application chamber 410.

In the baking chamber 510, when the substrate W is seated by the application robot 421, the substrate W may be heat treated. In the baking chamber 510, a prebake process for removing an organic matter or moisture from the surface of the substrate W by heating the substrate W to a predetermined temperature, before applying the processing liquid, a soft bake process performed after applying the processing liquid to the wafer W, or the like may be performed, and a cooling process performed to cool the substrate W after each heating process, or the like may be performed.

The baking chamber 510 may be equipped with a heating plate 511 and a cooling plate 512. The cooling plate 512 may be provided with a cooling means such as a coolant or a thermoelectric element.

In the cooling chamber 520, a cooling process may be performed to cool the substrate W before applying the processing liquid. The cooling chamber 520 may be provided with a cooling plate. The cooling plate may include a cooling means that may be used in various manners to cool the substrate W, such as cooling using a coolant, cooling using a thermoelectric element, or the like.

The interface module 600 may connect the applying/development module 400 to the exposure device 800 externally. The interface module 600 may include an interface frame 610, a first interface buffer 620, a second interface buffer 630, and a transfer robot 640, and, after an operation of the applying/development module 400 is completed, the transfer robot 640 may transfer the substrate returned to the first and second interface buffers 620 and 630 to the exposure device 800. The first interface buffer 620 may include a housing 621 and a support 622, and the transfer robot 640 may load/unload the substrate W into/out of the support 622.

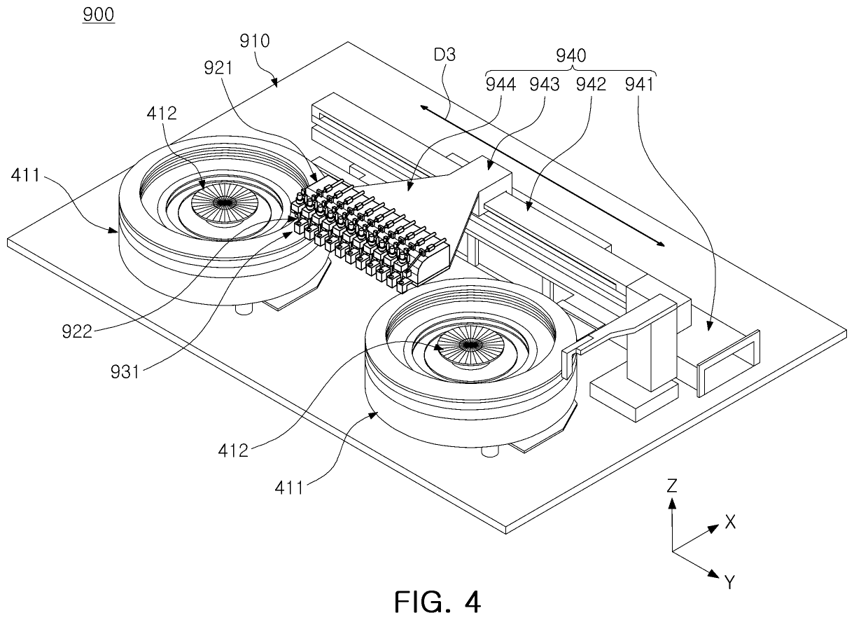

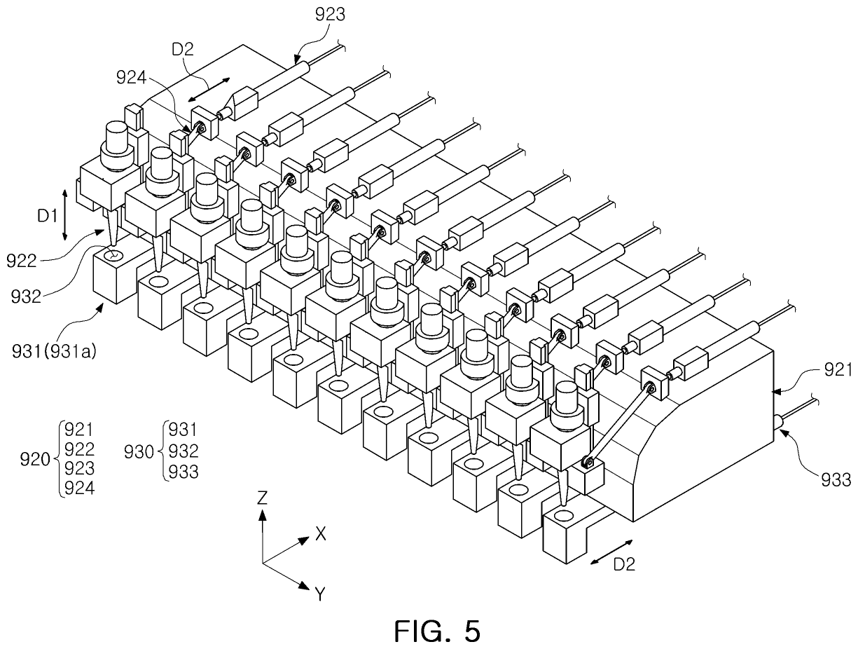

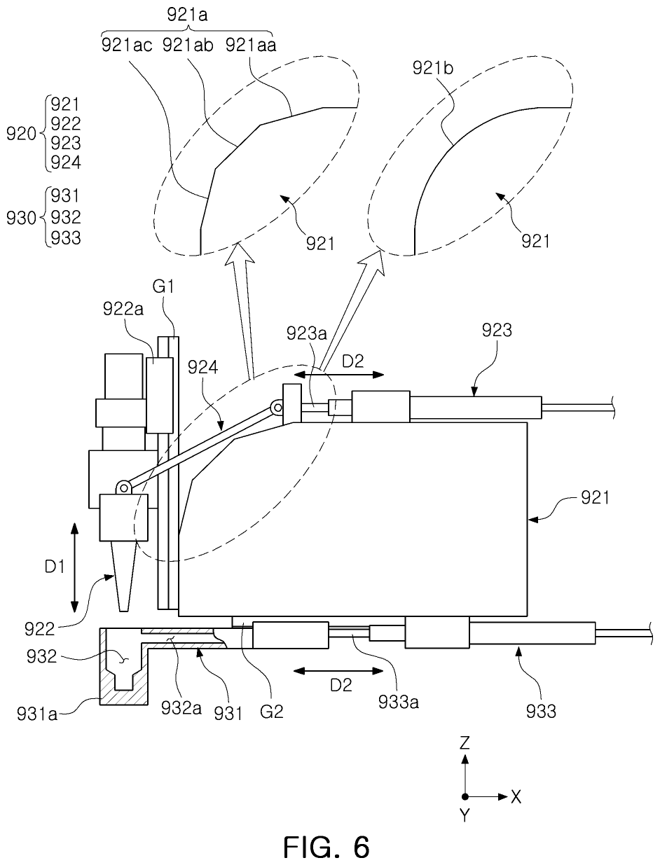

FIG. 4 is a perspective view illustrating a nozzle module and a peripheral portion thereof according to an embodiment of the present disclosure. FIG. 5 is an enlarged perspective view of a portion of the nozzle module of FIG. 4. FIG. 6 is a side view illustrating the nozzle module of FIG. 4, viewed from one side.

Referring to FIGS. 4 to 6, a nozzle module 900 may be disposed in a processing chamber of a substrate processing apparatus 1, and may include a base portion 910, a nozzle unit 920, and a vessel unit 930. Additionally, the nozzle module 900 may further include a support unit 940. In this case, the processing chamber may be an application chamber 410 included in an application module 401, as described above, but the present disclosure is not limited thereto.

The nozzle unit 920 and the vessel unit 930 may be supported on the base portion 910. As an example, the base portion 910 may be a bottom surface of the application chamber 410. However, the present disclosure is not limited thereto, and the base portion 910 may be a support (not illustrated) separately disposed in the application chamber 410.

The nozzle unit 920 may apply a processing liquid to a substrate W supported on a support portion 412 in a processing vessel 411. In this case, the nozzle unit 920 may include a first body 921 and a nozzle portion 922. Additionally, the nozzle unit 920 may further include a first driver 923 and a conversion member 924.

Other components of the nozzle module 900 may be connected to and supported on the first body 921. The first body 921 may have, for example, a rectangular hexahedral shape or a shape similar thereto, but the present disclosure is not limited thereto. In this case, the first body 921 may be provided with an inclined surface portion 921a.

The inclined surface portion 921a may be disposed on one side end of the first body 921. More specifically, the inclined surface portion 921a may be disposed between upper and lower surfaces of the first body 921 based on a height direction (third direction) Z of the first body 921. In this case, the one side end of the first body 921 in which the inclined surface portion 921a is formed may be adjacent to the nozzle portion 922, and may be an end portion of the first body 921 facing the nozzle portion 922. This inclined surface portion 921a may be formed to be inclined with respect to the third direction Z. More specifically, the inclined surface portion 921a may be inclined from the upper surface of the first body 921 toward the lower surface of the first body 921.

As illustrated in a left enlarged view of FIG. 6, the inclined surface portion 921a may be formed by connecting a plurality of inclined surfaces having different inclinations.

As an example, the inclined surface portion 921a may have a shape in which three inclined surfaces are connected. Hereinafter, the three inclined surfaces will be referred to as a first inclined surface 921aa, a second inclined surface 921ab, and a third inclined surface 921ac. In this case, the inclined surface portion 921a may be formed by continuously connecting the first inclined surface 921aa, the second inclined surface 921ab, and the third inclined surface 921ac.

More specifically, one end of the first inclined surface 921aa may be connected to an upper surface of the first body 921, and the other end of the first inclined surface 921aa may be connected to one end of the second inclined surface 921ab. The other end of the second inclined surface 921ab may be connected to one end of the third inclined surface 921ac, and the other end of the third inclined surface 921ac may be connected to a lower surface of the first body 921.

The inclined surfaces 921aa, 921ab, and 921ac may have different inclination angles. For example, based on a width direction (first direction) X of the first body 921, an inclination angle may increase from the first inclined surface 921aa to the second inclined surface 921ab and the third inclined surface 921ac. For example, an inclination angle of the third inclined surface 921ac may be greater than an inclination angle of the first inclined surface 921aa, and an inclination angle of the second inclined surface 921ab may be between the inclination angle of the first inclined surface 921aa and the inclination angle of the third inclined surface 921ac.

As another embodiment, as illustrated in a right enlarged view of FIG. 6, a curved portion 921b may be provided on the one side end of the first body 921, instead of the inclined surface portion 921a. In this case, the curved portion 921b may be disposed between the upper and lower surfaces of the first body 921, and may have a curved shape with a predetermined radius of curvature.

The nozzle portion 922 may apply the processing liquid to a surface of the substrate W. In this case, the nozzle portion 922 may be provided with a suck-back portion (not illustrated). The suck-back portion may suck-back a portion of the processing liquid remaining in a lower end portion (tip) of the nozzle portion 922 to an upper end portion of the nozzle portion 922, even after application is completed. As a result, it is possible to prevent contamination of the lower end portion of the nozzle portion 922, and an accommodation portion 932, which will be described later, due to the remaining portion of the processing liquid.

The nozzle portion 922 may reciprocate in a first movement direction D1. In this case, the first movement direction D1 may be parallel to the height direction Z of the first body 921. Therefore, the nozzle portion 922 may be raised and lowered in the height direction Z of the first body 921. In this case, the first body 921 may be provided with a first guide rail G1 extending in the third direction Z. Additionally, the nozzle portion 922 may include a first guide member 922a. The first guide member 922a may be slidably connected to the first guide rail G1, and may guide the nozzle portion 922 to reciprocate in the first movement direction D1.

The nozzle portion 922 may be disposed on one side of the first body 921 to face the inclined surface portion 921a. Additionally, the nozzle portion 922 may be disposed above the vessel unit 930, which will be described later. More specifically, the nozzle portion 922 may be disposed between the first driver 923 and the accommodation portion 932.

The nozzle portion 922 may have a shape extending from an upper side of the accommodation portion 932 toward the accommodation portion 932. In this case, the nozzle portion 922 may be raised in the first movement direction D1, and may move away from the accommodation portion 932, or may be lowered in the first movement direction D1 such that a lower end portion of the nozzle portion 922 may be accommodated in the accommodation portion 932.

The first driver 923 may generate driving force (hereinafter referred to as first driving force) necessary for movement of the nozzle portion 922. The first driver 923 may be formed of, for example, an actuator using pneumatic or hydraulic pressure, a linear motor operated by electromagnetic interaction, or the like. In this case, the first driver 923 may be disposed in an upper end portion of the first body 921.

More specifically, the first driver 923 may be fixedly coupled to an upper surface of the first body 921. In this case, the first driver 923 may include a first connection member 923a. The first connection member 923a may transmit the first driving force to the conversion member 924, which will be described later. By the first driving force, the first connection member 923a may reciprocate linearly in a second movement direction D2. In this case, the second movement direction D2 may be different from the first movement direction D1. For example, the second movement direction D2 may be perpendicular to the first movement direction D1, and may be parallel to the width direction (first direction) X of the first body 921.

The conversion member 924 may be disposed between the first driver 923 and the nozzle portion 922 to connect the first driver 923 and the nozzle portion 922. In this case, one end of the conversion member 924 may be connected to the first connection member 923a, and the other end of the conversion member 924 may be connected to an upper end portion of the nozzle portion 922. This conversion member 924 may transmit the first driving force received from the first connection member 923a to the nozzle portion 922.

The conversion member 924 may convert linear movement of the first connection member 923a from the second movement direction D2 to a direction, different from the second movement direction D2. As an example, the conversion member 924 may be provided with ball joints at both ends, and may be connected to the first connection member 923a and the nozzle portion 922 therethrough, to convert from the second movement direction D2 to the first movement direction D1. As another example, the conversion member 924 may be formed by rotatably combining several link portions, such that the second movement direction D2 may be converted to the first movement direction D1. In this case, the nozzle portion 922 may be slidably coupled to the first guide rail G1, to be guided in the first movement direction D1, when a direction of the movement is converted by the conversion member 924.

As described above, the inclined surface portion 921a (or curved portion 921b) may be provided on one side end of the first body 921 facing the nozzle portion 922 to form a space between the first body 921 and the conversion member 924. As a result, when the conversion member 924 rotates by the first driving force, the first body 921 may not interfere with rotation of the conversion member 924.

A processing liquid remaining after being applied to the substrate W from the nozzle portion 922 may flow into the vessel unit 930, and may be accommodated therein. Additionally, after the application of the processing liquid is completed or when the nozzle portion 922 is cleaned, a cleaning liquid used therein may flow into the vessel unit 930, and may be accommodated therein. In this case, the vessel unit 930 may be disposed to face the nozzle unit 920, and may include a second body 931 and an accommodation portion 932. Additionally, the vessel unit 930 may further include a second driver 933.

The second body 931 may be disposed on one side of the first body 921. In an embodiment, the second body 931 may be disposed below the first body 921. In this case, the upper surface of the second body 931 may be spaced apart from a lower surface of the first body 921 by a predetermined distance. In this arranged state, the second body 931 may be configured to reciprocate in the second movement direction D2, which will be described later.

The second body 931 may include a protrusion 931a. The protrusion 931a may be disposed on one end of both end portions of the second body 931 disposed in the longitudinal direction (first direction) X of the second body 931. The protrusion 931a may be formed to protrude from the one end of the second body 931 in a downward direction. In this case, the one end (hereinafter referred to as the protruding end) of the second body 931 may be an end portion facing the nozzle portion 922 located above the vessel unit 930.

The accommodation portion 932 may be a groove in which a lower end portion of the nozzle portion 922 is accommodated when the nozzle portion 922 is lowered in the first movement direction D1. The processing liquid discharged from the nozzle portion 922 may be accommodated in the accommodation portion 932. In addition, the accommodation portion 932 may be provided with a cleaning liquid spraying portion (not illustrated) for cleaning the nozzle portion 922, and the cleaning liquid sprayed therefrom may be accommodated in the accommodation portion 932.

The accommodation portion 932 may be disposed in the second body 931. More specifically, the accommodation portion 932 may be disposed on a protruding end portion of the second body 931. In this case, the accommodation portion 932 may be formed as a groove formed concavely inward (in a downward direction of the drawing) on an upper surface of the protruding end portion of the second body 931.

The accommodation portion 932 may be connected to a discharge fluid passage 932a. The discharge fluid passage 932a may be a passage for discharging the processing liquid and the cleaning liquid, flowed into and contained in the accommodation portion 932. As an example, the discharge fluid passage 932a may be formed in the second body 931. In this case, one end of the discharge fluid passage 932a may be connected to the accommodation portion 932, and the other end of the discharge fluid passage 932a may extend through an interior of the second body 931. An external discharge line (not illustrated) may be connected to the other end of the discharge fluid passage 932a, such that the processing liquid and the cleaning liquid passing through the discharge fluid passage 932a may be discharged to an outside of the substrate processing apparatus 1. In this case, the external discharge line may be formed of a flexible material such that the external discharge line does not interfere with movement of the nozzle unit 920 and movement of the vessel unit 930. Additionally, a liquid discharge device (not illustrated), such as an ejector or the like, may be installed in the external discharge line to provide suction force for discharging the processing liquid and the cleaning liquid.

As another example, although not illustrated in the drawings, the discharge fluid passage 932a may be connected to the accommodation portion 932 and extend to an outside of the second body 931. In this case, the one end of the discharge fluid passage 932a may communicate with a lower end portion of the accommodation portion 932, and the other end of the discharge fluid passage 932a may extend to the outside of the second body 931. The used processing liquid and cleaning liquid may be discharged to the outside of the substrate processing apparatus 1 through the discharge fluid passage 932a. In a similar manner to the above-described embodiment, the discharge fluid passage 932a may be formed of a flexible material, and of course, a liquid discharge device (not illustrated), such as an ejector or the like, may be installed in the discharge fluid passage 932a.

The second driver 933 may generate driving force (hereinafter referred to as second driving force) for reciprocating the second body 931. The second driver 933 may be formed of, for example, an actuator using pneumatic or hydraulic pressure, a linear motor operated by electromagnetic interaction, or the like.

The second driver 933 may be disposed on the first body 921. For example, the second driver 933 may be fixedly coupled to the lower surface of the first body 921. In this case, the second driver 933 may include a second connection member 933a. The second connection member 933a may be disposed between the second body 931 and the second driver 933. In this case, the second connection member 933a may connect the second body 931 and the second driver 933, to transmit the second driving force to the second body 931. More specifically, by the second driving force, the second connection member 923a may reciprocate linearly in the second movement direction D2, and the second body 931 connected thereto may reciprocate linearly integrally with the connection member 933a in the same direction D2.

The support unit 940 may be disposed on the base portion 910, as illustrated in FIG. 4. The nozzle unit 920 and the vessel unit 930 may be supported by the support unit 940. In this case, a support 941, a guide portion 942, a connection portion 943, and a support plate 944 may be provided.

The support 941 may be fixedly coupled to the base portion 910. The support 941 may have a shape extending in one direction. In this case, a direction in which the support 941 extends may be parallel to a third movement direction D3, which may be a movement direction of the connection portion 943. In this case, the third movement direction D3 may be a direction in which a plurality of processing vessels 411 disposed in the application chamber 410 are arranged. The third movement direction D3 may be different from the first movement direction D1 and the second movement direction D2. For example, the third movement direction D3 may be a longitudinal direction of the first body 921, for example, a direction parallel to the second direction Y.

The guide portion 942 may be disposed on the support 941. As an example, the guide portion 942 may be disposed on an upper surface of the support 941, and may extend in the third movement direction D3, which may be a longitudinal direction of the support 941. The guide portion 942 may be formed as, for example, a guide rail.

The connection portion 943 may be disposed between the nozzle unit 920 and the support 941. In this case, one end of the connection portion 943 may be movably connected to the guide portion 942 on the support 941, and the other end of the connection portion 943 may be connected to the support plate 944. The connection portion 943 may be configured to linear reciprocate along the guide portion 942 in the third movement direction D3. In this case, the connection portion 943 may move integrally with the support plate 944 connected to the connection portion 943.

The support plate 944 may support the nozzle unit 920. The support plate 944 may be a plate having various shapes. In the drawings, the support plate 944 may have a minimum area in a portion connected to the connection portion 943, and only a configuration in which an area gradually increases as a distance from the connection portion 943 increases is illustrated, but the present disclosure is not limited thereto.

The nozzle unit 920 may be connected to the support plate 944. For example, the first body 921 of the nozzle unit 920 may be fixedly coupled to one side surface of the support plate 944. As another example, the first body 921 of the nozzle unit 920 may be fixedly coupled to an upper surface of the support plate 944, and in this case, the second driver 933 of the vessel unit 930 may be fixedly coupled to a lower surface of the support plate 944. Therefore, when the connection portion 943 moves along the guide portion 942, the support plate 944, and the nozzle unit 920 and the vessel unit 930, coupled thereto, may move together in the third movement direction D3.

The above-described nozzle unit 920 and vessel unit 930 may each be provided in plural. The plurality of nozzle units 920 may have the nozzle portion 922, the first driver 923, and the conversion member 924, provided in plural, installed on one first body 921. However, the present disclosure is not limited thereto, and the nozzle units 920 may be each configured to separately have the first body 921, and may have a configuration arranged in a row in the third movement direction D3 on the support plate 944. In this case, the plurality of vessel units 930 may be arranged to face the nozzle portions 922 one to one. Therefore, when the nozzle portions 922 are raised and lowered, a lower end portion of each of the nozzle portions 922 may be accommodated in the accommodation portion 932 of the vessel unit 930 in which each of the nozzle portions 922 faces.

As above, when a plurality of nozzle units 920 and a plurality of vessel units 930 are provided, each of the nozzle portions 922 may be configured to independently raise and lower in the first movement direction D1. In addition, the second bodies 931 may be also configured to independently reciprocate linearly in the second movement direction D2, which will be described in detail below.

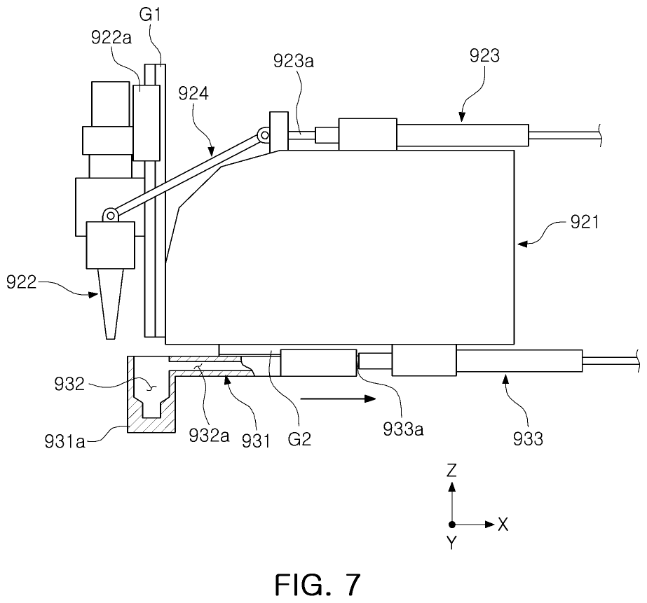

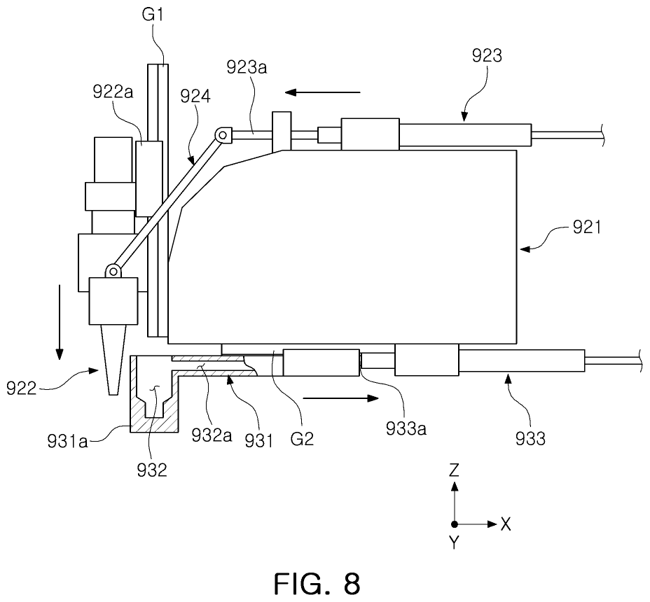

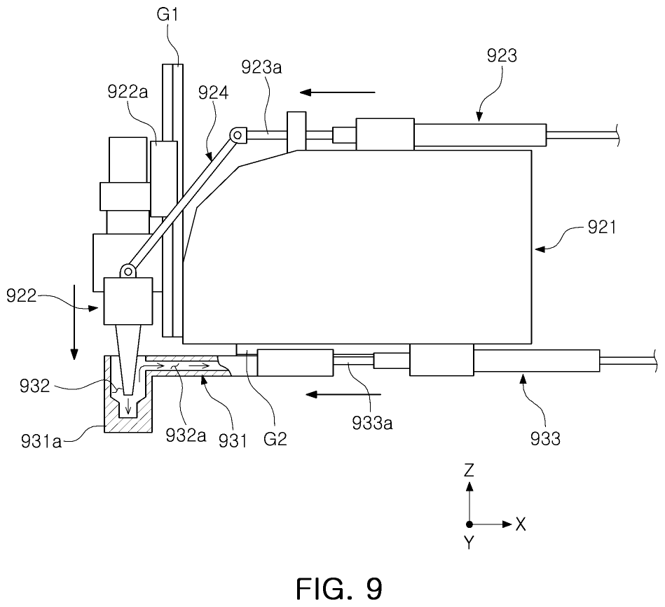

FIG. 7 is a side view illustrating one state of the nozzle module of FIG. 4. FIG. 8 is a side view illustrating another state of the nozzle module of FIG. 4. FIG. 9 is a side view illustrating the other state of the nozzle module of FIG. 4.

Referring to FIGS. 7 to 9, operations of a nozzle unit 920 and a vessel unit 930, included in a nozzle module 900, according to the present disclosure, may be as follows.

The nozzle module 900 may apply a processing liquid onto substrates W in a plurality of processing vessels 411 disposed in an application chamber 410. In this case, a support unit 940 may linearly reciprocate the nozzle unit 920 in the third movement direction D3. Therefore, the nozzle unit 920 may apply the processing liquid to a surface of a substrate W in one processing vessel 411 among the processing vessels 411, and may then move in the third movement direction D3 to apply the processing liquid to a substrate W in another processing vessel 411.

In this manner, while the nozzle unit 920 and the vessel unit 930 moves by the support unit 940, as illustrated in FIG. 7, a nozzle portion 922 may be disposed on a higher level than the vessel unit 930, and a second body 931 of the vessel unit 930 may be in a state moved inward (in a right direction in the drawing) in the second movement direction D2 (hereinafter referred to as a first state). By moving while maintaining the first state, it is possible to prevent a protrusion 931a of the second body 931 from being caught by a side wall of the processing vessel 411 or the like to interrupt movement of the nozzle unit 920.

When the nozzle unit 920 moves onto an upper side of the processing vessel 411 and applies the processing liquid on the substrate W, only the nozzle portion 922 may be lowered in the first movement direction D1 due to first driving force, while the second body 931 of the vessel unit 930 is maintained in the same state as the first state. Therefore, the nozzle portion 922 may move to a position adjacent to an upper surface of the substrate W and be in a state directly facing the substrate W (hereinafter referred to as a second state). In the second state, the nozzle portion 922 may apply the processing liquid on the substrate W, such that application of the processing liquid may not be interrupted by the second body 931 of the vessel unit 930.

After the application of the processing liquid to one of the processing vessels 411 is completed, or when the nozzle portion 922 needs to be cleaned, the support unit 940 may move the nozzle unit 920 in a region between the processing vessels 411 (hereinafter referred to as a nozzle cleaning region). Upon arriving at the nozzle cleaning region, the second body 931 may move outward (in a left direction in the drawing) by second driving force. Therefore, the second body 931 moves below the nozzle portion 922, such that the nozzle portion 922 and an accommodation portion 932 may be arranged to face each other. Then, by the first driving force transmitted through a conversion member 924, the nozzle portion 922 may be lowered in the first movement direction D1, such that a lower end portion of the nozzle portion 922 may be in an accommodated state in the accommodation portion 932 (hereinafter referred to as a third state).

When disposed in the third state in the nozzle cleaning region, the nozzle portion 922 may be cleaned by spraying the cleaning liquid toward the nozzle portion 922 from a cleaning liquid spraying portion (not illustrated) in the accommodation portion 932. The cleaning liquid used for the cleaning may be discharged through a discharge fluid passage 932a. In this case, the processing liquid remaining on the lower end of the nozzle portion 922 or the processing liquid on an outer surface of the lower end portion of the nozzle portion 922 may be cleaned and discharged, together with the cleaning liquid.

As described above, when the nozzle portion 922 and the vessel unit 930 are provided in plural, the nozzle portions 922 may operate independently. More specifically, only one of the nozzle portions 922 may be lowered, or only a portion of the nozzle portions 922 may be lowered. In this case, only the lowered nozzle portion 922 may apply the processing liquid on the substrate W. Additionally, when the nozzle portion 922 is cleaned, only the second body 931 corresponding to the lowered nozzle portion 922 may move to a position facing the nozzle portion 922, to be used for applying the processing liquid or only the nozzle portion 922 necessary for cleaning may be cleaned.

Afterwards, when cleaning of the nozzle portion 922 is completed, the nozzle unit 920 and the vessel unit 930 may move from the nozzle cleaning region to the next processing vessel 411 by the support unit 940. Thereafter, a process of applying the processing liquid to the substrate W, and a process of cleaning the nozzle may be repeatedly performed.

As described above, a nozzle module 900 and a substrate processing apparatus 1 including the same, according to embodiments of the present disclosure, may include a plurality of nozzle portions 922 that may be raised and lowered, and a plurality of vessel units 930 that may reciprocate horizontally. The nozzle portions 922 may be configured to operate independently, such that when a processing liquid is applied or cleaning is required, only a nozzle portion 922 corresponding thereto may be lowered and processed. As a result, waste of liquids such as processing liquids, cleaning liquids, or the like, used in a substrate processing process, may be prevented, and unnecessary cleaning work may be avoided, to improve substrate processing efficiency and semiconductor device productivity.

In the above embodiments, a substrate processing apparatus of the present disclosure has been described as an embodiment applied to a photo process, but the present disclosure is not limited thereto. As long as the substrate processing apparatus is used as a device for using a processing liquid and a device for cleaning the same in a substrate processing process, it is obvious to those skilled in the art that the present disclosure may be applied to various processes such as an etching process, a testing process, a packaging process, or the like, and the applications will also fall in the scope of the present disclosure.

A nozzle module and a substrate processing apparatus including the same, according to embodiments of the present disclosure, may include a plurality of nozzle portions that may be raised and lowered and a plurality of vessel units that may move horizontally and reciprocally, and each of the nozzle portions may be configured to be independently operable, to apply a processing liquid, or, cleaning is required, only a nozzle portion concerned therewith may be lowered for processing. Therefore, waste of liquids such as a processing liquid, a cleaning liquid, or the like, used in a processing process of a substrate may be prevented, and unnecessary cleaning work may be avoided, to improve substrate processing efficiency and semiconductor device productivity.

While example embodiments have been illustrated and described above, it will be apparent to those skilled in the art that modifications and variations could be made without departing from the scope of the present disclosure as defined by the appended claims.

What is claimed is:

1. A nozzle module comprising:
a base portion;
a nozzle unit disposed on the base portion, and including a first body, and a nozzle portion reciprocating in a first movement direction; and
a vessel unit disposed to face the nozzle unit, and including a second body reciprocating in a second movement direction, and an accommodation portion concavely formed inwardly from an upper surface of the second body.

2. The nozzle module of claim 1, further comprising a support unit including a support member disposed on the base portion, a guide portion disposed on the support member, a connection portion connected to the guide portion to reciprocate in a third movement direction, and a support plate connecting the connection portion and the nozzle unit.

3. The nozzle module of claim 1, wherein the nozzle portion is disposed above the second body, and extends toward the accommodation portion in a downward direction.

4. The nozzle module of claim 1, wherein the nozzle unit further comprises a first driver disposed on an upper surface of the first body to generate driving force necessary for moving the nozzle portion, and a conversion member disposed between the first driver and the nozzle portion to convert a direction of the driving force to the first movement direction.

5. The nozzle module of claim 4, wherein the nozzle portion is raised and lowered between the first driver and the accommodation portion.

6. The nozzle module of claim 4, wherein the vessel unit further comprises a second driver coupled to a lower surface of the first body and generating driving force necessary for movement of the second body.

7. The nozzle module of claim 6, wherein one end of the second body is connected to the second driver and extends in the second movement direction, and the other end of the second body is bent downwardly in the first movement direction.

8. The nozzle module of claim 4, wherein an inclined surface portion is provided on one end of the first body.

9. The nozzle module of claim 1, wherein the nozzle portion and the vessel unit are provided in plural, respectively, and
the plurality of nozzle portions and the plurality of vessel units are arranged to face each other one to one, and each of the plurality of nozzle portions is operable independently.

10. A substrate processing apparatus comprising:
a processing chamber;
at least two processing units disposed in the processing chamber, including a processing vessel accommodating a substrate, and a support portion disposed in the processing vessel and supporting the substrate; and
a nozzle module disposed in the processing chamber, and including a base portion, a nozzle unit disposed on the base portion, and including a first body, and a nozzle portion reciprocating in a first movement direction, a vessel unit disposed to face the nozzle unit, and including a second body reciprocating in a second movement direction, and an accommodation portion concavely formed inwardly from an upper surface of the second body, and a support unit including a support member disposed on the base portion, a guide portion disposed on the support member, a connection portion connected to the guide portion to reciprocate in a third movement direction, and a support plate connecting the connection portion and the nozzle unit.

11. The substrate processing apparatus of claim 10, wherein the support unit reciprocates in the third movement direction, to move the nozzle unit from one processing unit among the at least two processing units to a different processing unit.

12. The substrate processing apparatus of claim 10, wherein the nozzle portion is disposed above the second body, and extends toward the accommodation portion in a downward direction.

13. The substrate processing apparatus of claim 10, the nozzle unit further comprising a first driver disposed on an upper surface of the first body to generate driving force necessary for moving the nozzle portion, and a conversion member disposed between the first driver and the nozzle portion to convert a direction of the driving force to the first movement direction.

14. The substrate processing apparatus of claim 13, wherein the nozzle portion is raised and lowered between the first driver and the accommodation portion.

15. The substrate processing apparatus of claim 13, wherein the vessel unit further comprises a second driver coupled to a lower surface of the first body and generating driving force necessary for movement of the second body.

16. The substrate processing apparatus of claim 15, wherein one end of the second body is connected to the second driver and extends in the second movement direction, and the other end of the second body is bent downwardly in the first movement direction.

17. The substrate processing apparatus of claim 13, wherein an inclined surface portion is provided on one end of the first body.

18. The substrate processing apparatus of claim 10, wherein the nozzle portion is provided in plural, and the plurality of nozzle portions are spaced apart in a longitudinal direction of the first body, and at least a portion of the plurality of nozzle portions operate independently.

19. The substrate processing apparatus of claim 18, wherein the vessel unit is provided in plural, and
the plurality of vessel units are arranged to face the plurality of nozzle portions one to one, and the second body independently reciprocates.

20. A substrate processing apparatus comprising:
a processing chamber;
at least two processing units disposed in the processing chamber, including a processing vessel accommodating a substrate, and a support portion disposed in the processing vessel and supporting the substrate; and
a nozzle module disposed in the processing chamber, and including a base portion, a nozzle unit disposed on the base portion, and including a first body, a nozzle portion reciprocating in a first movement direction, a first driver disposed on an upper surface of the first body to generate driving force necessary for moving the nozzle portion, and a conversion member disposed between the first driver and the nozzle portion to convert a direction of the driving force to the first movement direction, a vessel unit disposed to face the nozzle unit, including a second body reciprocating in a second movement direction, and an accommodation portion concavely formed inwardly from an upper surface of the second body, and disposed to face the nozzle portion, and a support unit including a support member disposed on the base portion, a guide portion disposed on the support member, a connection portion connected to the guide portion to reciprocate in a third movement direction, and a support plate connecting the connection portion and the nozzle unit,
wherein the nozzle portion is disposed above the second body, and extends toward the accommodation portion in a downward direction, and is raised and lowered between the first driving portion and the accommodation portion,
one end of the first body has an inclined surface portion,
the inclined surface portion is disposed below the conversion member, and is formed by connecting a plurality of inclined surfaces having different inclination angles,
the nozzle portion is provided in plural, the plurality of nozzle portions are arranged to be spaced apart in a longitudinal direction of the first body, and at least a portion of the plurality of nozzle portions is independently raised and lowered, and
the vessel unit is provided in plural, the plurality of vessel units are arranged to face the plurality of nozzle portions one to one, and at least a portion of the second body independently reciprocates.
